(19) United States
(12) Patent Application Publication
(10) Pub. No.: US 2010/0055413 A1
(43) Pub. Date: Mar. 4, 2010

(54) ARTICLE, AND A METHOD FOR CREATING THE ARTICLE, WITH A CHEMICALLY PATTERNED SURFACE

(75) Inventors: Jas Pal Singh Badyal, County Durham (GB); James McGettrick, County Durham (GB); L. G. Harris, County Durham (GB)

Correspondence Address: CLARK & ELBING LLP, 101 FEDERAL STREET, BOSTON, MA, 02110, US

(73) Assignee: UNIVERSITY OF DURHAM, Durham City (GB)

(21) Appl. No.: 11/919,185

(22) PCT Filed: Apr. 28, 2006
(86) PCT No.: PCT/GB2006/001570

§ 371 Date: Nov. 18, 2009

(30) Foreign Application Priority Data
May 4, 2005 (GB) 0509213.5

(51) Int. Cl. B32B 3/00; B05D 7/00; C23C 16/50

(52) U.S. Cl. 428/195.1; 427/256; 427/569

(57) ABSTRACT

The invention relates to the provision of an article and a method of forming an article with a surface which can have at least one sub-layer and a top layer of material. At least one part of the top layer is selectively removed to expose at least one sub-layer and/or the surface of the substrate and allow the functionality of the sub-layer and/or surface to be utilised in the area(s) where it is exposed. The top layer, where it remains, acts as a barrier to the sub-layer and/or surface being exposed to the surrounding environment. Typically parts of the top layer are removed in a patterned manner to provide a series of predefined areas at which the sub-layer or sub-layers are selectively exposed.

The invention relates to a method for creating an article including a substrate with at least one surface that is patterned with a chemical functionality with at least one portion of said surface having a different chemical and/or physical property which differs to that of the remainder of said surface.

The chemical patterning of solid surfaces is of crucial importance within many technological fields, including genomic/proteomic array manufacture, microelectronics, sensors, and microfluidics. Methods currently employed to pattern surfaces include: photolithography, laser ablation, surface embossing, block co-polymer segregation, and soft-lithography. Many of these techniques have inherent restrictions, most often the need for highly planar, chemically specific substrates, the employment of expensive lasers and prefabricated masks, and the environmentally unsound use of solvents and corrosive agents.

A general means of producing accurate patterns of any chemical functionality, upon any surface or article, without recourse or limitation to specific chemistries and solvents, is hence a useful and innovative addition to the art.

The preferred use of plasma techniques, to generate at least one of the utilised coatings or surfaces, renders the method of even greater and more wide-spread utility. Plasma techniques are recognised as being a clean, dry, energy and materials efficient alternative to standard wet chemical methods for producing surfaces bearing tailored functionalities.

Plasmas have been successfully employed within previous methods for patterning surfaces. Plasma polymer deposition through a mask has been used to pattern carbon nanotubes (Chen et al, Appl. Phys. Lett. 2000, 76, 2719), conducting polymers (Dai et al, J. Phys. Chem. B, 1997, 101, 9548), and cells (France et al, Chem. Mater. 1998, 10, 1176). However, these techniques are restricted to flat, planar substrates (e.g. silica or glass) in order to maintain the prerequisite dose physical contact with the mask and ensure adequately high-definition reproduction of its features.

Alternative approaches that can utilise aspects of plasma patterning include nanosphere lithography, and the application of photolithography techniques. In the case of nanosphere lithography, it is difficult to extend the pattern over large areas, whereas photolithography critically depends upon the application of photo-resists and the vulnerability of the substrate towards radiation damage.

According to this invention in a first aspect there is provided a method for the fabrication of a chemically and/or physically patterned surface on a substrate, said method including the provision of at least one homogeneous sub-layer of a desired chemical functionality and wherein a chemically distinct material is applied to form a further or top layer which presents a physical and chemical barrier to the at least one sublayer or surface and the pattern is created by selectively removing at least part of the said further or top layer.

In one embodiment the at least one sublayer is formed by means including the deposition of at least one material to form the layer and/or by modifying the surface of the substrate to form the layer.

There is therefore provided in one embodiment a method for the fabrication of high-definition chemically and physically patterned surfaces on non-planar substrates. Said method typically initially comprises the generation of a homogeneous layer(s) of desired chemical functionality(s), by means that include the deposition of a coating(s) bearing said functionality(s), or by otherwise appropriately modifying the surface of the substrate. The chemically distinct top-layer can then be applied which presents a physical and chemical barrier to the interaction of the sub-layer(s) with the environment. The pattern can be directly created by selectively removing the top layer by physical means, for example by scratching it away or by puncturing it with a sharp tip. The removal of the top-layer by tribological ablation reveals the underlying functionality(s), spatially restricted to the desired pattern by the surrounding extant top layer. The active sub-layer(s) may then be utilized by any means as are known in the art.

In one embodiment a series of sublayers or coatings may be successively applied to the substrate before the application of the top or further layer i.e. that the cited functionalised under-layer itself comprises a manifold of layers. Abrasion of the resultant multi-layer stack to varying depths would then permit the formation of a variety of features displaying different, possibly multiple, functionalities. Suitable means for achieving the required variable depth of abrasion/coating removal are a robotic microarray spotter equipped with a series of pins of differing lengths, or alternatively a solid surface furnished with protrusions of differing lengths.

Chemically functionalised layers that may be patterned with great subsequent utility include a range of chemically reactive polymers that may either be reacted/derivatized further or possess inherently useful properties (including, but not restricted to, hydrophobicity, bio-activity, protein attachment, protein resistance, cell adhesion and DNA binding).

A specific example of such a functionalised polymer is poly(glycidyl methacrylate) which has the ability to covalently bind nucleophiles such as amines. A surface bearing a pattern of poly(glycidyl methacrylate) hence has great utility in creating spatially addressed arrays of amine terminated bio-molecules, such as derivatized strands of DNA and proteins.

Other polymers that possess great utility when applied in surface patterns include, but are not limited to: aldehyde functionalised polymers, such as poly(3-vinylbenzaldehyde) and poly(10-undecenal), that can be subsequently derivatised with amine functionalised bio-molecules; thiol functionalised polymers, such as poly(allyl mercaptan), that can be subsequently derivatised with thiol terminated moieties (via disulphide bridge chemistry); pyridine functionalised polymers, such as poly(4-vinyl pyridine), that are both superhydrophilic and can be subsequently derivatised or quaternized with species that include haloalkanes; and halogen functionalised polymers, such as poly(2-bromoethylacrylate) and poly(4-vinylbenzyl chloride), that can be used as initiating sites for grafting procedures (for example, Atom Transfer Radical Polymerisation).

In alternative embodiments of the invention, the patterned functionalised layer may be non-polymeric in nature. Suitable examples include metals, semiconductors, non-metallic elements, ceramics, and other inorganic surfaces such as silicon nitride and titanium dioxide. Silicon dioxide surfaces are particularly useful because of their amenability to coupling reactions with a huge range of readily available alkoxysilane and chlorosilane reagents.

The functional surfaces listed above are intended to be illustrative rather than limiting. It should be evident to anyone versed in the art that a huge range of functional groups exist that may prove beneficial if patterned according to the method of the invention. In fact, any functionalities that confer contrasting properties to those of the top-layer they are partnered with may be suitable for use in the invention. Examples of properties that may grant value to a substrate when exposed in a pattern include, but are not restricted to, hydrophobicity. hydrophilicity, specific chemical reactivity, chemical sensing ability, wear resistance, gas barrier, filtration, anti-reflective behaviour, controlled release, liquid or stain resistance, enhanced lubricity, adhesion, protein resistance, biocompatibility, bio-activity, the encouragement of cell growth, and the ability to selectively bind biomolecules.

The top-layer that is applied over the functional surface should present a barrier to any interactions of its under-layer(s) with the environment over the timescale of its intended use. In addition, said top layer should be soft enough to facilitate removal by means of physical wear (e.g. scratching or puncturing), thus revealing the functionalised under-layer in the desired pattern. Particularly suitable layers for this purpose are thin polymeric, metallic, or inorganic coatings that are substantially inert and insoluble with respect to both their functionalised under-layer and any subsequent procedures (e.g. chemical derivatisation).

In one embodiment of the invention the top-layer is a polymeric in nature. In a particularly preferred embodiment of the invention, the top-layer is a thin pulsed plasma polymer film. In a further preferred embodiment of the invention, the top-layer is a thin, pulsed plasma polymerised film of polystyrene.

The optimum thickness of said top-layer utilised in the method of the invention depends upon a number of factors. These include the barrier characteristics of the top-layer material with respect to any external environments it may experience, the properties of the underlying functional surface and their effective range, the substrate characteristics (e.g. composition, degree of planarity, roughness), and the means of top-layer removal to be employed (e.g. scratching with the tip of a Scanning Probe Microscope, puncturing with the pin of a micro-arrayer, or embossing).

The most fundamental concern is that the top-layer is sufficiently thick to prevent any significant interaction of the underlying functional surface with the environment. Thus creating a contrast between areas where the top-layer has been removed, and surrounding areas of functionality shielded by extant top-layer.

In embodiments of the invention where the patterned functionality interacts by virtue of direct contact with its environment, the top-layer may be very thin. For example, if the functionalised under-layer comprises a reactive polymer, such as poly(glycidyl methacrylate), that, after patterning, is to be used to directly bind bio-molecules (such as amine-terminated strands of DNA), the shielding top-layer only requires sufficient durability to present a chemical and diffusional obstacle to solution-phase DNA binding chemistry. These barrier conditions may be met by a thin film of any substantially inert and insoluble material, e.g. polystyrene, less than 1000 nm thick, and most preferably less than 200 nm thick. Said top-layers are sufficiently thin to permit easy removal by the probe-tips of Scanning Probe Microscopes (such as Atomic Force Microscopes and related devices). This removal method facilitates the production of patterns at very small scales, with feature sizes of less than 100 μm (most particularly of less than 1 μm) being possible. Patterns at this scale (nm-μm) possess great potential utility in the manufacture of high-throughput DNA and protein microarrays.

A variety of means may be used to generate the layers used in the method of the invention. The initial, functionality-bearing layer(s), may be created by applying a coating (or coatings) to a substrate, by chemically modifying a pre-existing surface (e.g. by wet chemical modification or by using a plasma surface treatment), or it may comprise the innate surface functionality of the substrate (for example, the reactive silanol functionality inherent to silica surfaces renders them well suited to patterning without further modification).

Where the creation of a layer used in the method of the invention is achieved by the application of a coating, any means that is known in the art may be utilised. Suitable methods include, but are not limited to: wet chemical deposition, plasma deposition, chemical vapour deposition, electroless deposition, photochemical deposition, spin-coating, solvent casting, spraying, polymerization, graft polymerization, electron beam deposition, and ion bean deposition.

The top-layer (which acts as a barrier and is later selectively removed) may be deposited on top of the initial, functionality-bearing layer by any means as are known in the art (including, but not limited to, spin-coating, solvent casting, spraying, chemical vapour deposition, and plasma methods). The only limitation is that the means of generating the top-layer should not damage or otherwise compromise the utility of the functional layer(s) underneath (except by presenting a physically removable barrier to its interaction with the environment).

In a specific embodiment of the method, the functionality-bearing layer(s) are deposited onto the substrate by means of non-equilibrium plasmas operating at either low pressure, sub-atmospheric pressures, or atmospheric pressure.

In another specific embodiment of the method, the top-layer (which acts as a barrier and is later selectively removed) is a coating deposited onto the functionality-bearing layer by means of a non-equilibrium plasma operating at either low pressure, sub-atmospheric pressures, or atmospheric pressure.

Hence, in preferred embodiments of the invention, either or both of the layers (the under-layer that bears the functionality to be patterned, and the barrier top-layer) are coatings deposited by means of non-equilibrium plasmas.

In further preferred embodiments of the invention the plasma deposited coatings are deposited by means of pulsed plasma polymerisation techniques.

A variety of procedures may be used to selectively remove the top-layer from the functionalised under-layer. Said means are preferably physical in nature and rely upon tribological abrasion to remove the barrier layer and expose the functional layer in the desired spatial pattern. Especially favoured techniques are those that permit the preparation of micron and nano scale features. Such patterns are the most difficult to prepare by alternative means and permit the preparation of a variety of devices, including but not limited to: high throughput genomic/proteomic arrays, microelectronics, sensors, and microfluidics.

In a preferred embodiment of the invention the probe-tip(s) of a Scanning Probe Microscope (SPM) or a related device is used to selectively remove the top-layer and expose the functionalised under-layer. In a further preferred embodiment of the invention, said SPM is an Atomic Force Microscope (AFM, the tip(s) of which is rastered across the sample surface in such a way that the top-layer is removed, exposing the functional layer underneath in the desired pattern. Using said method it is possible to create an enormous variety of features (troughs, squares etc), in a wide range of sizes, with a high degree of control. The minimum feature size capable of being created by SPM-based methods is a function of the radius of the probe tip (typically <10 nm), whilst the only inherent limit on the maximum feature size is the range of the scanner employed (typically 1-1000 μM).

In another embodiment of the method of the invention, the pin of a microarrayer is used to puncture the top-layer and expose the reactive under-layer. Microarraying devices (such as those manufactured by Genetix Limited, Hampshire, United Kingdom) are normally used to generate protein/DNA arrays, utilising a pin to transfer small droplets of protein/DNA solution from storage wells, onto a reactive surface at spatially addressed sites (“spotting”). In a preferred embodiment of the method of the invention, the spotting pin of a said microarraying device is configured so that it penetrates the top-layer, exposing the functional surface underneath. The size and shape of the features created by this technique are a function of the cross-sectional area of the pin, typically 1-200 μm. This top-layer removal step may evidently be accompanied by the simultaneous delivery of a droplet of liquid, enabling the concomitant patterning and derivatization of a surface. The utilisation in the method of a top-layer that acts as a barrier to any droplet interaction with the functional layer outside of the pin diameter, enables spotting at far higher resolutions than is possible using existing microarraying techniques.

In further preferred embodiment of the method, where the top-layer is applied over a multi-layered stack of functional coatings, it is required that the means of coating removal can be applied to differing depths. The application of said means of removal permits the formation of features displaying different combinations of exposed functionality on the same substrate. Apparatuses capable of delivering the necessary variable depth of abrasion/coating removal include robotic microarray spotters equipped with a multitude of pins of differing lengths, solid surfaces furnished with protrusions of differing lengths, and embossing devices.

The means of top-layer removal cited above are intended to be illustrative rather than limiting. It will be evident to anyone versed in the art that a huge range of abrasive techniques and implements may be used to remove the top-layer. The only limitation is that applied means of top-layer removal must not significantly compromise the utility of the functional layer underneath.

However, of special utility are those means of top-layer removal capable of creating patterns and features at scales sufficiently small to enable the production of biological microarrays. For said purpose, features of less than 100 μm are especially desirous.

In a further aspect of the invention there is provided an article in the form of a substrate having at least one surface or sub-layer with a first chemical and/or physical functionality and a top layer applied thereover having a differing chemical and/or physical functionality wherein part of said top layer is selectively removed to expose the material of said surface and/or sub-layer.

In a preferred embodiment at least one sublayer is applied to the substrate, with said top layer applied thereover. In one embodiment a plurality of sub-layers are applied and the top layer and selected sub-layer(s) are removed to selectively expose the material of the selected sub-layers at predefined parts of the substrate.

Typically parts of the material of the top layer are removed to form a preferred pattern of exposed areas of the sub-layer and/or surface.

The top layer typically acts as a barrier to exposure of the covered surface and/or sub-layer to the external environment.

In preferred embodiments of the invention either or both of the layers (the under-layer that bears the functionality to be patterned, and the barrier top-layer) are plasma polymers. Plasma polymers are typically generated by subjecting a coating-forming precursor to an ionising electric field under low-pressure conditions. Although atmospheric-pressure and sub-atmospheric pressure plasmas (including atomised spray devices) are known and utilised for this purpose in the art. Deposition occurs when excited species generated by the action of the electric field upon the precursor (radicals, ions, excited molecules etc.) polymerise in the gas phase and react with the substrate surface to form a growing polymer film.

However, it has been noted that the utility of plasma deposited coatings is often compromised by excessive fragmentation of the coating forming precursor during plasma processing. This problem has been addressed in the art by pulsing the applied electrical field in a sequence that yields a very low average power thus limiting monomer fragmentation and increasing the resemblance of the coating to its precursor (i.e. improving “monomer retention”). Examples of such sequences include those in which the plasma is on for 20 μs and off for from 1000 μs to 20000 μs. International Patent Application number WO9858117 (The Secretary of State for Defense, GB) describes such a process in which oil repellent coatings are produced by the pulsed plasma polymerisation of perfluorinated acrylate monomers.

Precise conditions under which pulsed plasma deposition of the coating(s) utilised in the method of the invention takes place in an effective manner will vary depending upon factors such as the nature of the monomer(s), the substrate, the size and architecture of the plasma deposition chamber etc. and will be determined using routine methods and/or the techniques illustrated hereinafter. In general however, polymerisation is suitably effected using vapours or atomised droplets of the monomers at pressures from 0.01 to 1000 mbar. The most suitable plasmas are those that operate at low pressures i.e. less than 10 mbar, particularly at approximately 0.2 mbar. Although atmospheric-pressure (greater than or equal to 1000 mbar) and sub-atmospheric pressure (10 to 1000 mbar) plasmas are known and utilised for plasma polymer deposition in the art.

A glow discharge is then ignited by applying a high frequency voltage, for example at 13.56 MHz. The applied fields are suitably of an average power of up to 50 W.

The fields are suitably applied for a period sufficient to give the desired coating. In general, this will be from 30 seconds to 60 minutes, preferably from 1 to 15 minutes, depending upon the nature of the monomer(s), the substrate and the intended purpose of the plasma polymer film (i.e. functional coating or barrier top-layer) etc.

Suitably, the average power of the pulsed plasma discharge is low, for example of less than 0.05 W/cm³, preferably less than 0.025 W/cm³ and most preferably less than 0.0025 W/cm³.

The pulsing regime which will deliver such low average power discharges will vary depending upon the nature of the substrate, the size and nature of the discharge chamber etc. However, suitable pulsing arrangements can be determined by routine methods in any particular case. A typical sequence is one in which the power is on for from 10 μs to 100 μs, and off for from 1000 μs to 20000 μs.

Suitable plasmas for use in the method of the invention include non-equilibrium plasmas such as those generated by audio-frequencies, radiofrequencies R or microwave frequencies. In another embodiment the plasma is generated by a hollow cathode device. In yet another embodiment, the pulsed plasma is produced by direct current (DC).

The plasma(s) may operate at low, sub-atmospheric or atmospheric pressures as are known in the art. The monomer(s) may be introduced into the plasma as a vapour or an atomised spray of liquid droplets (WO03101621 and WO03097245, Surface Innovations Limited). The monomer(s) may also be introduced into the pulsed plasma deposition apparatus continuously or in a pulsed manner by way of, for example, a gas pulsing valve

The substrate to which the coating(s) are applied will preferentially be located substantially inside the pulsed plasma during coating deposition. However, the substrate may alternatively be located outside of the pulsed plasma, thus avoiding excessive damage to the substrate or growing coating.

The monomer(s) will typically be directly excited within the plasma discharge. However, “remote” plasma deposition methods may be used as are known in the art. In said methods the monomer enters the deposition apparatus substantially “downstream” of the pulsed plasma, thus reducing the potentially harmful effects of bombardment by short-lived, high-energy species such as ions.

In alternative embodiments of the invention, materials additional to the plasma polymer coating precursor(s) are present within the plasma deposition apparatus. The additional materials may be introduced into the coating deposition apparatus continuously or in a pulsed manner by way of, for example, a gas pulsing valve.

Said additive materials may be inert and act as buffers without any of their atomic structure being incorporated into the growing plasma polymer (suitable examples include the noble gases). A buffer of this type may be necessary to maintain a required process pressure. Alternatively the inert buffer may be required to sustain the plasma discharge. For example, the operation of atmospheric pressure glow discharge (APGD) plasmas often requires large quantities of helium. This helium diluent maintains the plasma by means of a Penning Ionisation mechanism without becoming incorporated within the deposited coating.

In other embodiments of the invention, the additive materials possess the capability to modify and/or be incorporated into the coating forming material and/or the resultant plasma deposited coating. Suitable examples include other reactive gases such as halogens, oxygen, and ammonia.

In a further aspect of the invention there is provided a method forming a chemically patterned surface on a substrate said method comprising the steps of creating a surface bearing the desired chemical functionality(s), wholly covering the said surface with a substantially disparate layer of material; and removing selected portions of said layer by means of physical contact to generate a plurality of exposed portions of said surface.

In one embodiment the portions are removed so as to form a spatial pattern of said portions with said chemical functionality(s).

In one embodiment the exposed portions are subsequently modified by means of any chemical or biological reaction or interaction.

In one embodiment plasma deposition is used to generate either, or both, the desired functional surface and/or said layer.

The invention will now be particularly described by way of examples with reference to the accompanying drawings in which:

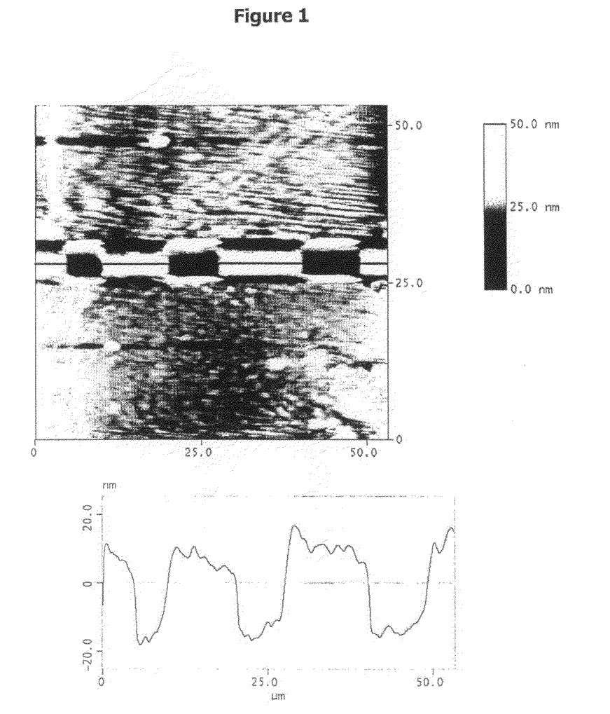

FIG. 1 shows a topographic AFM image and cross-sectional analysis of a patterned pulsed plasma polymer bi-layer deposited on a silicon substrate, comprising 20 nm of polystyrene on top of a 1500 nm thick coating of poly(glycidyl methacrylate), selectively abraded with the AFM probe tip before imaging.

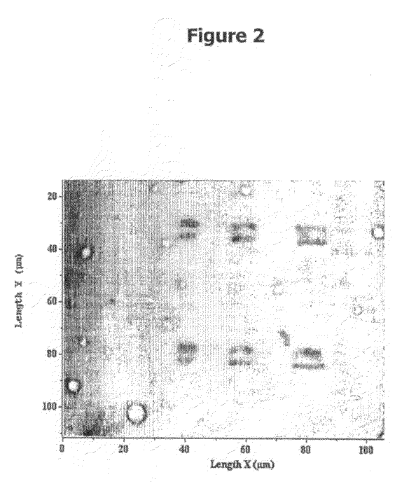

FIG. 2 shows an optical image of a patterned pulsed plasma polymer bi-layer deposited on a silicon substrate, comprising 20 nm of polystyrene on top of a 1500 nm thick coating of poly(glycidyl methacrylate), selectively abraded with the AFM probe tip before imaging.

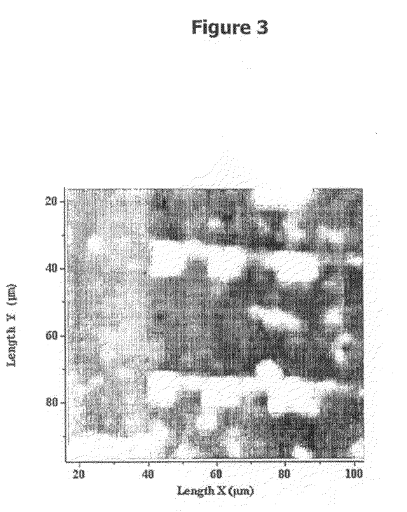

FIG. 3 shows a fluorescence map of a patterned pulsed plasma polymer bi-layer deposited on a silicon substrate, comprising 20 nm of polystyrene on top of a 1500 nm thick coating of poly(glycidyl methacrylate), selectively abraded with the AFM probe tip and subsequently derivatized with an amine functionalized dye (cresyl violet perchlorate) before imaging.

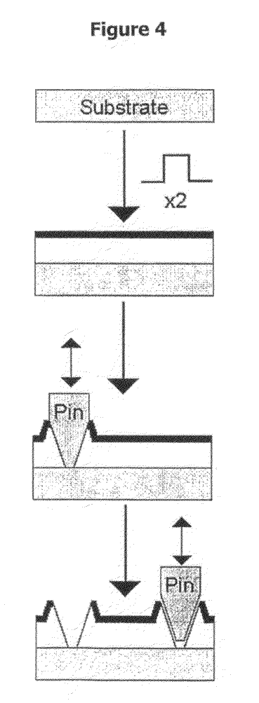

FIG. 4 is a scheme showing the manufacture of micro-well arrays. The substrate is first treated with a reactive plasma polymer (white layer), which is then masked with a second, inert plasma polymer (the thin, dark layer). The pin of a robotic microarray spotter is then used to repeatedly puncture the surface, producing an array of micro-wells containing exposed, reactive plasma polymer.

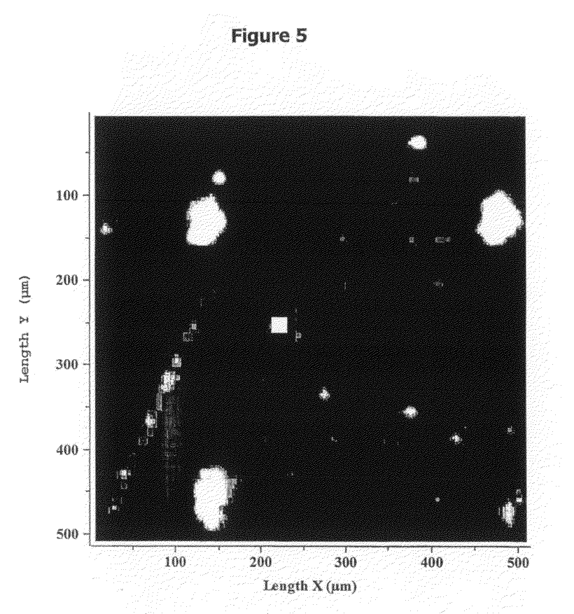

FIG. 5 shows a fluorescence microscopy image of a Cy5-tagged oligonucleotide derivatized micro-well array manufactured on a bi-layer of poly(3-vinylbenzaldehyde) and polystyrene plasma polymers. The size and pitch of the bright regions corresponds to the impact of the spotting tip, and confirms exposure of the reactive poly(3-vinylbenzaldehyde) layer.

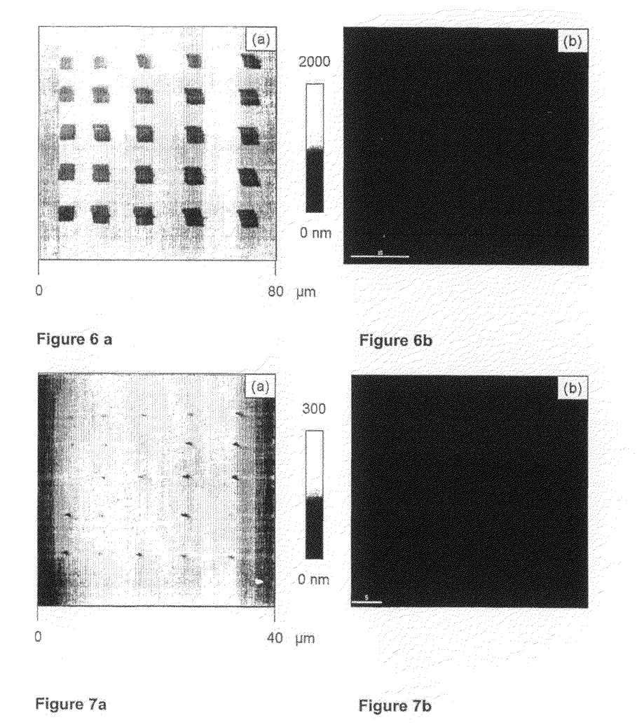

FIGS. 6a and b show an AFM micrograph and fluorescence image respectively showing 5 μm×5 μm squares created via SPM probe scratching arranged in a 5×5 array and the fluorescence image following exposure to Protein G solution and then complementary Alexa Fluor 633 IgG.

FIGS. 7a and b show an AFM micrograph and fluorescence image respectively showing 500 nm×500 nm squares created via SPM probe scratching arranged in a 5×5 array following exposure to Protein G solution and then complementary Alexa Fluor 633 IgG.

The following examples are intended to illustrate the present invention but are not intended to limit the same:

### EXAMPLE 1

Pulsed plasma polymerisation was used to deposit a reactive layer of poly(glycidyl methacrylate) upon a silicon-wafer substrate. The resultant epoxide functionalised surface was then covered with a top-layer of polystyrene, again by pulsed plasma polymerisation. Patterning was achieved by using an Atomic Force Microscope (AFM) probe-tip to scratch away areas of this polystyrene barrier layer. The exposed areas of under-lying poly(glycidyl methacrylate) functionality were then selectively derivatized using an amine functionalised fluorescent dye. The efficacy of patterning was confirmed by fluorescence microscopy.

The pulsed plasma deposition of the initial poly(glycidyl methacrylate) functional layer was performed as follows. Glycidyl methacrylate (Fluka, >97% purity) plasma polymer precursor was loaded into a resealable glass tube and purified using several freeze-pump-thaw cycles. Pulsed plasma polymerization of the epoxide-functionalised monomer was carried out in a cylindrical glass reactor (4.5 cm diameter, 460 cm³ volume, 2×10⁻³ mbar base pressure, 1.4×10⁻⁹ mols⁻¹ leak rate) surrounded by a copper coil (4 mm diameter, 10 turns, located 15 cm away from the precursor inlet) and enclosed in a Faraday cage. The chamber was evacuated using a 30 L min⁻¹ rotary pump, attached via a liquid nitrogen cold trap, and the pressure monitored with a Pirani gauge. All fittings were grease-free. During pulsed plasma deposition the radiofrequency power supply (13.56 MHz) was triggered by a square wave signal generator with the resultant pulse shape monitored using an oscilloscope. The output impedance of the RF power supply was matched to the partially ionised gas load using an L-C matching network.

Prior to use, the apparatus was thoroughly cleaned by scrubbing with detergent, rinsing in propan-2-ol, and oven drying. At this stage the reactor was reassembled and evacuated to base pressure. Further cleaning comprised running a continuous wave air plasma at 0.2 mbar and 40 W for 30 minutes. Next, a silicon wafer (10 mm×15 mm) was inserted into the centre of the reactor and the system re-evacuated to base pressure. Monomer vapour was then introduced into the chamber at a pressure of 0.2 mbar for 5 min prior to plasma ignition.

Optimum epoxide functional group retention at the surface was found to require 40 W continuous wave bursts lasting 20 μs (tₒₙ) interspersed by off-periods (t_{off}) of 20000 μs. The average power delivered to the system during this pulsing regime was hence 0.04 W. After 60 minutes of deposition, the RF generator was switched off and the precursor allowed to purge through the system for a further 5 minutes. Finally, the chamber was re-evacuated to base pressure and vented to atmosphere.

X-ray photoelectron spectroscopy (XPS), Fourier Transform Infra-red Spectroscopy (FT-IR) and reflectometry confirmed the creation of a 1565 nm thick layer of poly(glycidyl methacrylate) on the silicon wafer.

The subsequent deposition of the polystyrene top-layer was achieved using an analogous pulsed plasma polymerisation procedure to that described above. Styrene monomer (Sigma, >99% purity, further purified by several freeze-pump-thaw cycles) was polymerized in an identical plasma deposition apparatus, at a vapour pressure of 0.2 mbar, for 5 minutes, using 40 W continuous wave bursts lasting 100 μs (tₒₙ), interspersed by off-periods (t_{off}) of 4000 μs (the average power was hence 0.98 W).

The presence of a ˜20 nm thick over-layer of polystyrene on top of the epoxide coated silicon wafers was confirmed by XPS, reflectometry, and water contact angle measurements (the water contact angle increased from 64°±4°, indicative of poly(glycidyl methacrylate), to 86°±1°, indicative of polystyrene).

Patterning of the plasma deposited poly(glycidyl methacrylate)/polystyrene bi-layer was both executed and observed using an Atomic Force Microscope Digital Instruments Nanoscope III, equipped with control module, extender electronics and a signal access module). Three areas of the polystyrene top-layer were physically scratched away using a tapping mode tip (Nanoprobe, spring constant 42-83 N/m) applied in contact mode in the selected pattern using a program written in the Veeco Nanolithography Software (Version 5.30r1). Images of the patterned samples were afterwards obtained in contact mode at scan rate of 1 Hz. Topographic and cross-sectional analyses confined the creation of three areas (5×5 μm, 5×6 μm, and 5×10 μm) where the polystyrene top-layer had been removed to a depth of ˜20 nm, FIG. 1.

The success of the AFM-mediated physical patterning approach was shown by the attachment of an amine functionalized dye to the exposed epoxide moieties of the underlying poly(glycidyl methacrylate) film. Dyeing comprised immersing the patterned sample in a 1% w/v aqueous solution of cresyl violet perchlorate (Sigma) for 1 hour before rinsing in distilled water for 24 hours and drying. A fluorescence microscope system (LABRAM, Tobin Yvon Ltd, equipped with a 633 nm He—Ne laser) was used to optically image and fluorescently map the patterned surface, FIG. 2 and FIG. 3. Fluorescence mapping clearly showed that the attachment of the cresyl violet dye was restricted to the areas of poly(glycidyl methacrylate) exposed within the abraded squares. This confirms that pulsed plasma polymerisation is a suitable methodology for the production of both the functional and barrier layers of the invention, and that an AFM probe tip is an effective, highly controllable means of top-layer removal.

### EXAMPLE 2

Pulsed plasma polymerisation was used to deposit a reactive layer of poly(3-vinylbenzaldehyde) onto a borosilicate glass coverslip. The resultant aldehyde functionalised coating was then screened with an inert top-layer of polystyrene, again by pulsed plasma polymerisation. Patterning was performed using the pin of a robotic microarray spotter to punch through the polystyrene barrier layer, exposing areas of the underlying poly(3-vinylbenzaldehyde), FIG. 4. These aldehyde functionalised microwells were then selectively reacted with a fluorescently tagged, amine-terminated oligonucleotide, using reductive amination chemistry.

Pulsed plasma polymerization was performed using a broadly identical apparatus and procedure to that described in Example 1. Pulsed plasma deposition of the reactive poly(3-vinylbenzaldehyde) layer was performed from 3-vinylbenzaldehyde monomer (Aldrich, 97% purity, further purified by repeated free-pump-thaw cycles) at a vapour pressure of 0.2 mbar, for 5 minutes, using 40 W continuous wave bursts lasting 50 μs (tₒₙ), interspersed by off-periods (t_{off}) of 4000 μs (the average power was hence 0.49 W). XPS analysis and reflectometry confirmed the deposition of a 200 nm thick film possessing good structural retention of the monomer functionality.

The subsequent deposition of a polystyrene top layer utilized the same plasma parameters described in Example 1. However, a longer deposition duration resulted in a ˜180 nm thick over-layer of polystyrene on top of the aldehyde coated glass coverslip.

The resultant poly(3-vinylbenzaldehyde)/polystyrene bi-layer system was patterned using a robotic microarray spotter, equipped with a stainless steel pin, to puncture holes in the sample surface. This procedure generated an array of micro-wells (print pitch=350 μm) containing exposed poly(3-vinylbenzaldehyde).

The successful creation of accessible aldehyde functionality was demonstrated by its derivatization with a Cy5-fluorophore tagged oligonucleotide using reductive amination chemistry. This procedure comprised immersion of the patterned sample in a pH 4.5 saline sodium citrate buffer containing the probe nucleotide (Sigma-Genosys, oligonucleotide sequence: 5′-3′ AACGATGCACGAGCA, desalted, reverse phase purified with 3′ terminal primary amine and 5′ terminal Cy5 fluorophore) at 42° C., for 16 hours. Subsequently 3.5 mg ml⁻¹ NaCN(BH₃) (Aldrich, 99%) was added and the solution gently stirred for a further 3 hours. Excess physisorbed oligonucleotides were then removed by sequential washing in high purity water; saline sodium citrate buffer (SSC, 0.3M Sodium Citrate, 3M NaCl, pH 7, Sigma) with 1% sodium dodecyl sulphate (Sigma, 10% solution); high purity water; solution of 10% stock SSC buffer in high purity water with 0.1% (w/v) sodium dodecyl sulphate; high purity water; 5% stock SSC buffer in high purity water; and finally, high purity water.

The attachment of the fluorescently tagged oligonucleotide to the array of exposed poly(3-vinylbenzaldehyde) sites was verified using a fluorescent microscope (LABRAM, Tobin Yvon Ltd, equipped with a 633 nm He—Ne laser). Fluorescence mapping clearly showed that the attachment of the Cy5-tagged oligonucleotide was restricted to the areas of poly(3-vinylbenzaldehyde) exposed on the walls of the micro-wells, and that the polystyrene over-layer acted as a substantially inert barrier to the reductive amination chemistry employed, FIG. 5.

This result demonstrates that pulsed plasma polymerisation is a suitable methodology for the production of both the functional and the barrier layers of the invention. In addition, a microarray spotting pin is shown to be an effective means of puncturing the inert top-layer enabling the creation of multiplex arrays of spatially-localised reactive sites.

### EXAMPLE 3

In a further example of the invention the following was performed for the preparation of protein arrays. Pulsed plasma polymerisation was used to deposit a protein reactive layer of poly(glycidyl methacrylate) onto a silicon wafer. The resultant epoxide functionalised surface was screened with a protein resistant overlayer of poly(N-acrylosarcosine methyl ester).

Patterning of the plasma deposited poly(glycidyl methacrylate)/poly(N-acrylosarcosine methyl ester) was both executed and observed using an atomic force microscope Digital Instruments Nanoscope III control module, extender electronics, and signal access module, Santa Barbara, Calif.). 5 μm×5 μm squares arranged in a 5×5 grid and 500 nm×500 nm squares in a 5×5 grid were created by scratching the surface using a tapping mode tip (Nanoprobe, spring constant 42-83 Nm⁻¹). Images of the patterned samples were obtained in tapping mode and confirmed the creation of the grids.

The successful creation of accessible protein reactive sites on a protein resistant surface was demonstrated by immobilisation of protein G from streptococcus sp (20 μg mL⁻¹ phosphate buffered saline) for 60 min at room temperature followed by successive washing in phosphate buffered saline, 50% phosphate buffered saline diluted with de-ionised water, and twice with de-ionized water. This was followed by exposure to a complementary solution of Alexa Fluor 633 Goat antimouse IgG (20 μg mL⁻¹ phosphate buffers saline) for 60 min. and successive washing in phosphate buffered saline, 50% phosphate buffered saline diluted with de-ionised water, and finally twice with de-ionized water.

Fluorescence mapping clearly indicates areas of fluorescence corresponding to the scratched areas of the patterned surface, demonstrating the successful binding of protein G and then complementary protein IgG to these areas. This indicates that the scratched pattern had penetrated through the protein resistant poly(N-acrylosarcosine methyl ester) top layer to the protein reactive poly(glycidyl methacrylate) underlayer.

FIG. 6 a illustrates an AFM micrograph showing 5 μm×5 μm squares created via SPM probe scratching arranged in a 5×5 array. FIG. 6(b) is the fluorescence image after immersion of the sample in Protein G and then complementary Alexa Fluor 633 IgG. The layers comprise of a protein reactive underlayer of pulsed plasma deposited poly(glycidyl methacrylate) onto a silicon wafer and a protein resistant overlayer of pulsed plasma deposited poly(N-acrylosarcosine methyl ester).

FIG. 7a shows an AFM micrograph of 500 nm×500 m squares created via SPM probe scratching arranged in a 5×5 array. FIG. 7b shows the fluorescence image after immersion of the sample in Protein G and then complementary Alexa Fluor 633 IgG. The layers comprise of a protein reactive underlayer of pulsed plasma deposited poly(glycidyl methacrylate) onto a silicon wafer and a protein resistant overlayer of pulsed plasma deposited poly(N-acrylosarcosine methyl ester).

In both FIGS. 6b and 7b it will be seen how the specific areas which have been exposed by the removal of the top coating of the material act to retain the Protein G whereas none is retained in the unexposed areas.

Thus the present invention illustrates the manner in which a chemically patterned surface can be created by the selective removal of portions of the surface and/or selected depths of the surface coatings so as to allow selected chemically active or inactive and/or particular chemical attributes to be exposed at the surface of the substrate for subsequent use.

1. A method for the fabrication of a chemically and/or physically patterned surface on a substrate, said method including the provision of at least one surface or homogeneous sub-layer of a desired chemical functionality and wherein a chemically distinct material is applied to form a further or top layer which presents a physical and chemical barrier to the at least one sublayer or surface and the pattern is created by selectively removing at least part of the said further or top layer.

2. A method according to claim 1 wherein the at least one sublayer is formed by means including the deposition of at least one material to form the sub-layer and/or by modifying the surface of the substrate.

3. A method according to claim 1 wherein the removal is performed using physical means.

4. A method according to claim 1 wherein where the top layer is removed reveals the underlying functionality of the first layer which is spatially restricted to the desired pattern by the surrounding extant top layer.

5. A method according to claim 1 wherein the at least one sub-layer material is utilized in the areas where the same has been exposed to the external environment.

6. A method according to claim 1 wherein a series of sub-layer coatings are successively applied to the substrate before the application of the top layer.

7. A method according to claim 6 wherein abrasion of the resultant multi-layer stack is performed to varying depths at selected areas to permit the formation of a variety of features displaying different, possibly multiple, functionalities at specified areas of the substrate surface.

8. A method according to claim 7 wherein a robotic microarray spotter equipped with a series of pins of differing lengths, is used to selectively remove material to the required depth.

9. A method according to claim 7 wherein a solid surface furnished with protrusions of differing lengths is used to provide the differing characteristics in different areas of the surface.

10. A method according to claim 1 wherein the at least one sub-layer which is formed includes any of a range of chemically reactive polymers that can be reacted/derivatized further.

11. A method according to claim 10 wherein the polymers include the properties of any, or any sub-section, of hydrophobicity, bio-activity, protein attachment, protein resistance, cell adhesion and/or DNA binding.

12. A method according to claim 10 wherein the polymer is poly(glycidyl methacrylate).

13. A method according to claim 12 wherein a substrate surface is created having a pattern of exposed poly(glycidyl methacrylate) on the surface creating spatially addressed arrays of amine terminated bio-molecules.

14. A method according to claim 13 wherein derivatized strands of DNA and proteins are created in the exposed areas of the substrate surface.

15. A method according to claim 10 wherein polymers used are any or any combination of aldehyde functionalised polymers that can be subsequently derivatised with amine functionalised bio-molecules; thiol functionalised polymers that can be subsequently derivatised with thiol terminated moieties, pyridine functionalised polymers that are superhydrophilic and can be subsequently derivatised or quaternized with species that include haloalkanes and/or halogen functionalised polymers that can be used as initiating sites for grafting procedures.

16. A method according to claim 1 wherein the at least one sub-layer is formed to be non-polymeric in nature.

17. A method according to claim 16 wherein materials to form the sub layer used include any or any combination of metals, semi-conductors, non-metallic elements, ceramics, and/or inorganic surfaces such as silicon nitride and titanium dioxide.

18. A method according to claim 1 wherein a material with a functionality that confers contrasting properties to those of a material used to form the top-layer is applied to form the at least one sub-layer.

19. A method according to claim 18 wherein properties that can be considered when the sub-layer is exposed in a pattern include any or any combination of hydrophobicity. hydrophilicity, specific chemical reactivity, chemical sensing ability, wear resistance, gas barrier, filtration, anti-reflective behaviour, controlled release, liquid or stain resistance, enhanced lubricity, adhesion, protein resistance, biocompatibility, bio-activity, the encouragement of cell growth, and/or the ability to selectively bind biomolecules.

20. A method according to claim 1 wherein the top-layer that is applied over the sub layer presents a barrier to any interactions with the covered sub-layer with the surrounding environment over a specified timescale.

21. A method according to claim 1 wherein the top layer is sufficiently soft to facilitate removal by means of physical wear to reveal the functionalised sub-layer in the desired pattern.

22. A method according to claim 1 wherein the top-layer is polymeric in nature.

23. A method according to claim 22 wherein the top-layer is a thin polymer film.

24. A method according to claim 1 wherein the top-layer is applied using a pulsed plasma.

25. A method according to claim 24 wherein the top layer is a thin, polymerised film of polystyrene applied using a pulsed plasma.

26. A method according to claim 1 wherein the top-layer is sufficiently thick to prevent any significant interaction of the covered sub-layer with the environment surrounding the substrate.

27. A method according to claim 1 wherein the at least one sub-layer comprises a reactive polymer to be used, where exposed, to directly bind bio-molecules and the top-layer presents a chemical and diffusional obstacle to solution-phase DNA binding chemistry

28. A method according to claim 27 wherein the top layer is substantially inert, insoluble and less than 1000 mm thick to permit removal by the probe-tips of a Scanning Probe Microscope to facilitate the production of a pattern at the surface with exposed areas of the sub-layer of less than 100 μm.

29. A method according to claim 1 wherein the at least one sub-layer is deposited onto the substrate by means of a non-equilibrium plasma.

30. A method according to claim 1 wherein the top layer is a coating deposited onto the at least one sub-layer by means of a non-equilibrium plasma.

31. A method according to claim 1 wherein a scanning probe microscope (SPM) or similar device is used to selectively remove the top-layer and expose the at least one sub-layer.

32. A method according to claim 29 wherein the SPM is an Atomic Force Microscope (AFM), the tip(s) of which is rastered across the surface to be removed such that the top-layer is removed, exposing the sub-layer underneath in the desired pattern.

33. A method according to claim 1 wherein the pin of a microarrayer is used to puncture the top-layer and expose the reactive under-layer.

34. A method according to claim 33 wherein a spotting pin of said micro-arraying device is configured to penetrate the top layer, exposing the functional surface underneath.

35. A method according to claim 32 wherein the step is accompanied by the simultaneous delivery of a droplet of liquid, enabling the concomitant patterning of the surface and derivatization of the exposed sub-layer.

36. A method according to claim 1 wherein at least one sub-layer is removed in addition to the top layer at least one location to form features displaying different combinations of exposed functionality on the same substrate.

37. A method according to claim 1 wherein either or both of the top and/or sub layers are plasma polymers.

38. A method according to claim 37 wherein the plasma used to apply the plasma polymers is pulsed.

39. A method according to claim 38 wherein a glow discharge is ignited by applying a high frequency voltage, with the applied fields having an average power of up to 50 W.

40. A method according to claim 38 wherein the pulsing sequence for the plasma is that the power is on from between 10 μs to 100 μs, and off from between 1000 μs to 20000 μs.

41. A method according to claim 39 wherein the substrate to which the coating(s) are applied is located substantially inside the pulsed plasma during coating deposition.

42. A method according to claim 39 wherein materials additional to the plasma polymer coating precursor(s) are present at the plasma deposition.

43. A method according to claim 42 wherein said additive materials are inert and act as buffers without any of their atomic structure being incorporated into the growing plasma polymer.

44. A method according to claim 42 wherein the additive material possesses the capability to modify and/or be incorporated into the coating forming material and/or the resultant plasma deposited coating.

45. A method for forming a chemically patterned surface on a substrate said method comprising the steps of creating a surface bearing the desired chemical functionality(s), wholly covering the said surface with a substantially disparate layer of material; and removing selected portions of said layer by means of physical contact to generate a plurality of exposed portions of said surface.

46. A method according to claim 45 wherein the portions are removed so as to form a spatial pattern of said portions with said chemical functionality(s).

47. A method according to claim 45 wherein the exposed portions are subsequently modified by means of any chemical or biological reaction or interaction.

48. A method according to claim 45 wherein plasma deposition is used to generate either, or both, the desired functional surface and/or said layer.

49. An article in the form of a substrate having at least one surface or sub-layer with a first chemical and/or physical functionality and a top layer applied thereover having a differing chemical and/or physical functionality wherein part of said top layer is selectively removed to expose the material of said surface and/or sub-layer.

50. An article according to claim 49 wherein at least one sublayer is applied to the substrate, with said top layer applied thereover.

51. An article according to claim 49 wherein parts of the material of the top layer are removed to form a preferred pattern of exposed areas of the sub-layer and/or surface.

52. An article according to claim 50 wherein a plurality of sub-layers are applied and the top layer and selected sub-layer(s) are removed to selectively expose the material of the selected sub-layers at predefined parts of the substrate.

53. An article according to claim 49 wherein the top layer acts as a barrier to exposure of the covered surface and/or sub-layer to the external environment.
